(19) United States
(12) Patent Application Publication
(10) Pub. No.: US 2026/0059693 A1
(43) Pub. Date: Feb. 26, 2026

(54) COOLING STRUCTURE OF LIDAR, LIDAR, AND VEHICLE

(71) Applicant: AUTOX TECH PTE. LTD., SINGAPORE (SG)

(72) Inventors: Jianxiong Xiao, Shenzhen (CN); Qing Deng, Shenzhen (CN); Yizhou Shan, Shenzhen (CN); Cheng Liu, Shenzhen (CN); Zhuo Li, Shenzhen (CN)

(73) Assignee: AUTOX TECH PTE. LTD., SINGAPORE (SG)

(21) Appl. No.: 19/214,302

(22) Filed: May 21, 2025

(30) Foreign Application Priority Data
Sep. 24, 2024 (CN) 2024113421515

(51) Int. Cl. H05K 7/20; G01S 7/481; G01S 17/931

(52) U.S. Cl. CPC H05K 7/20145; G01S 7/4813; G01S 17/931; H05K 7/20154; H05K 7/20172; H05K 7/20409

(57) ABSTRACT

A cooling structure of a LiDAR, a LiDAR, and a vehicle are provided. The cooling structure includes an upper compartment, a lower compartment, a driving device, and an impeller, the upper compartment, configured to mount an optical machine, is provided with an air duct, an air inlet and an air outlet; the air inlet is located at a bottom portion of the upper compartment, the air outlet is located at a top portion of the upper compartment; the lower compartment, connected to the upper compartment, is configured to support the upper compartment, the lower compartment supplies power to the upper compartment, and transmits signals; the driving device, connected between the upper compartment and the lower compartment, is configured to drive the upper compartment to rotate relative to the lower compartment; the impeller, connected to the driving device, creates airflow through the air inlet, and expels that through the air outlet.

### CROSS REFERENCE TO RELATED APPLICATION

This non-provisional patent application claims priority under 35 U.S.C. § 119 from Chinese Patent Application No. 202411342151.5 filed on Sep. 24, 2024, the entire content of which is incorporated herein by reference.

### TECHNICAL FIELD

This application relates to the technical field of LiDAR, particularly to a cooling structure of a LiDAR, a LiDAR, and a vehicle.

### BACKGROUND

As a core sensor in autonomous driving systems, LiDARs feature long detection ranges, high resolution, and round-the-clock operation. Unlike half-solid-state LiDARs and solid-state LiDARs, a mechanical rotating LiDAR can scan the surroundings with a 360-degree horizontal field of view, delivering comprehensive environmental data.

To precisely sense complex driving environments, enhancing the ranging and resolution capabilities of the LiDARs is a key technical goal. Increasing laser power boosts ranging, while adding more lasers improves resolution. However, both raise the heat generation of optical machines arranged in the LiDARs. Conventional natural-cooling methods are inefficient for high-heat-consumption scenarios. More cooling area is needed to dissipate the heat, yet this would significantly increase the size and weight of the LiDARs.

### SUMMARY

This application provides a cooling structure of a LiDAR, a LiDAR, and a vehicle.

In a first aspect, the cooling structure of the LiDAR provided includes an upper compartment, a lower compartment, a driving device, and an impeller, the upper compartment is configured to mount an optical machine for emitting laser, the upper compartment is provides with an air duct, and an air inlet and an air outlet that both communicated with the air duct; the air inlet is located at a bottom portion of the upper compartment facing towards the lower compartment, the air outlet is located at a top portion of the upper compartment away from the lower compartment; the lower compartment, connected to the upper compartment, is configured to support the upper compartment, the lower compartment supplies power to the upper compartment via wireless power supply, and transmits signals through wireless communication; the driving device, connected between the upper compartment and the lower compartment, is configured to drive the upper compartment to rotate relative to the lower compartment; the impeller is connected to the driving device, and is located between the upper compartment and the driving device, the impeller, driven by the driving device, rotates with the upper compartment, which creates the airflow that drawing external air in through the air inlet, and expel the airflow through the air outlet.

In a second aspect, the LiDAR provided includes the optical machine, and the cooling structure of the LiDAR, the cooling structure includes the upper compartment, the lower compartment, the driving device, and the impeller, the upper compartment is configured to mount the optical machine for emitting laser, the upper compartment is provides with the air duct, and the air inlet and the air outlet that both communicated with the air duct; the air inlet is located at the bottom portion of the upper compartment facing towards the lower compartment, the air outlet is located at the top portion of the upper compartment away from the lower compartment; the lower compartment, connected to the upper compartment, is configured to support the upper compartment, the lower compartment supplies power to the upper compartment via wireless power supply, and transmits signals through wireless communication; the driving device, connected between the upper compartment and the lower compartment, is configured to drive the upper compartment to rotate relative to the lower compartment; the impeller is connected to the driving device, and is located between the upper compartment and the driving device, the impeller, driven by the driving device, rotates with the upper compartment, which creates the airflow that drawing external air in through the air inlet, and expel the airflow through the air outlet.

In a third aspect, the vehicle provided includes a vehicle roof, and the LiDAR, the LiDAR is disposed on the vehicle roof, the LiDAR includes the optical machine, and the cooling structure of the LiDAR, the cooling structure includes the upper compartment, the lower compartment, the driving device, and the impeller, the upper compartment is configured to mount the optical machine for emitting laser, the upper compartment is provides with the air duct, and the air inlet and the air outlet that both communicated with the air duct; the air inlet is located at the bottom portion of the upper compartment facing towards the lower compartment, the air outlet is located at the top portion of the upper compartment away from the lower compartment; the lower compartment, connected to the upper compartment, is configured to support the upper compartment, the lower compartment supplies power to the upper compartment via wireless power supply, and transmits signals through wireless communication; the driving device, connected between the upper compartment and the lower compartment, is configured to drive the upper compartment to rotate relative to the lower compartment; the impeller is connected to the driving device, and is located between the upper compartment and the driving device, the impeller, driven by the driving device, rotates with the upper compartment, which creates the airflow that drawing external air in through the air inlet, and expel the airflow through the air outlet.

The cooling structure of the LiDAR, the LiDAR and the vehicle mentioned-above enhances LiDAR cooling by providing the air duct in the upper compartment of the LiDAR and utilizing the driving device to drive the impeller to rotate with the upper compartment, so as to create airflow that drawing external air in through the air inlet and expel the airflow through the air outlet, which actively cooling the LiDAR. This approach achieves the same cooling effect with less cooling area, reducing the size and weight of the LiDAR and significantly improving the cooling effect of the LiDAR. Additionally, the impeller rotates with the self-rotation of the LiDAR, eliminating extra motors or moving parts, resulting in a compact and highly efficient structure. Furthermore, the impeller, blowing external air inward, creates a positive pressure inside the air duct, reducing dust ingress.

### BRIEF DESCRIPTION OF THE DRAWINGS

In order to illustrate the technical solution in the embodiments of the disclosure or the prior art more clearly, a brief description of drawings required in the embodiments or the prior art is given below. Obviously, the drawings described below are only some of the embodiments of the disclosure. For ordinary technicians in this field, other drawings can be obtained according to the structures shown in these drawings without any creative effort.

FIG. 1 illustrates a overall-structure schematic diagram of a cooling structure of a LiDAR.

FIG. 2 illustrates a front-view schematic diagram of a cooling structure of a LiDAR.

FIG. 3 illustrates a structure schematic diagram of an impeller.

FIG. 4 illustrates a schematic diagram of a vehicle.

The realization of the purpose, functional characteristics and advantages of the disclosure will be further explained by referring to the attached drawings.

### DETAILED DESCRIPTION OF THE EMBODIMENTS

In order to make the purpose, technical solution and advantages of the invention more clearly, the invention is further described in detail in combination with the drawings and embodiments. It is understood that the specific embodiments described herein are used only to explain the invention and are not configured to define it. On the basis of the embodiments in the invention, all other embodiments obtained by ordinary technicians in this field without any creative effort are covered by the protection of the invention.

The terms “first”, “second”, “third”, “fourth”, if any, in the specification, claims and drawings of this application are configured to distinguish similar objects but need not be configured to describe any particular order or sequence of priorities. It should be understood that the data used here are interchangeable where appropriate, in other words, the embodiments described can be implemented in order other than what is illustrated or described here. In addition, the terms “include” and “have” and any variation of them, can encompass other things. For example, processes, methods, systems, products, or equipment that comprise a series of steps or units need not be limited to those clearly listed, but may include other steps or units that are not clearly listed or are inherent to these processes, methods, systems, products, or equipment.

It is to be noted that the references to “first”, “second”, etc. in the invention are for descriptive purpose only and neither be construed or implied the relative importance nor indicated as implying the number of technical features. Thus, feature defined as “first” or “second” can explicitly or implicitly include one or more such features. In addition, technical solutions between embodiments may be integrated, but only on the basis that they can be implemented by ordinary technicians in this field. When the combination of technical solutions is contradictory or impossible to be realized, such combination of technical solutions shall be deemed to be non-existent and not within the scope of protection required by the invention.

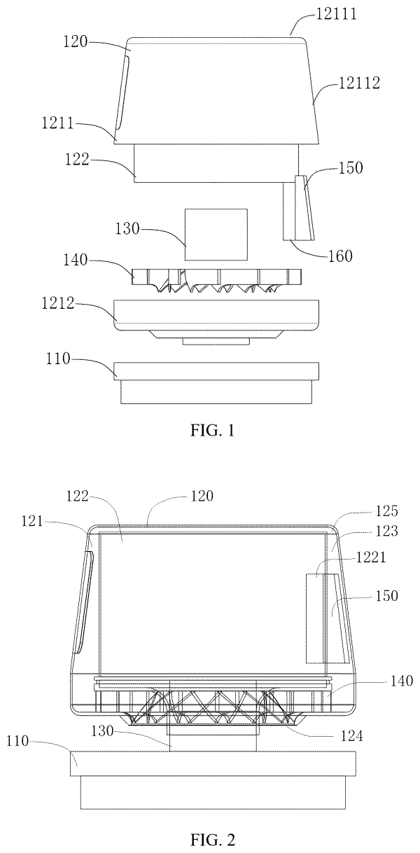

Referring to FIG. 1 and FIG. 2, a overall-structure schematic diagram of a cooling structure of a LiDAR is illustrated in FIG. 1, a front-view schematic diagram of a cooling structure of a LiDAR structure for LiDAR is illustrated in FIG. 2. A cooling structure 100 of a LiDAR provided is applied in LiDARs to provide cooling functionality. LiDARs are widely used in vehicles, ships, aircraft, robots, and the like. The cooling structure 100 for LiDAR includes a lower compartment 110, an upper compartment 120, a driving device 130, an impeller 140, and a heat sink 150.

The lower compartment 110 is disc-shaped and located directly below the upper compartment 120. As a stable component, the lower compartment 110 is configured to support the upper compartment 120 and the driving device 130. The lower compartment 110 supplies power to the upper compartment 120 via wireless power supply and transmits signals through wireless communication.

The upper compartment 120 is cylindrical. The upper compartment 120 includes an outer shell 121 and an inner shell 122. The outer shell 121 covers an outer side of the inner shell 122 and forms an air duct 123 for airflow and providing the basis for cooling, with a certain gap between the outer shell 121 and the inner shell 122. The inner shell 122, a sealed structure, protects internal components from dust and water. In this embodiment, the inner shell 122 is configured to seal an optical machine 160 located therein. The optical machine 160 is disposed on a sidewall of the inner shell 122.

The outer shell 121 includes an upper shell 1211 and a bottom shell 1212. The upper shell 1211 includes a top portion 12111 away from the lower compartment 110, and a side wall 12112 that extend downward from the edge of the top portion 12111 towards the lower compartment 110. The bottom shell 1212 is fixed to a bottom portion of the side wall 12112 away from the top portion 12111. The middle portion of the bottom shell 1212 is provided with a circular through-hole. The driving device 130 is embedded into the interior of the upper compartment 120 through the circular through-hole, nested and connected with the upper compartment 120. The bottom shell 1212 is a component for placing the impeller 140, which can rotate within the bottom shell 1212. An opening is provided at a bottom portion of the bottom shell 1212 to form an air inlet 124, which allows external air to enter the air duct 123. An air outlet 125 is disposed at the edge of the top portion 12111, above the air duct 123. Air flows through the air duct 123 and is discharged into the external environment through the air outlet 125.

The driving device 130 is connected between the upper compartment 120 and the lower compartment 110. The driving device 130 is configured to drive the upper compartment 120 to rotate relative to the lower compartment 110 when the LiDAR is in operation. The driving device 130 is provided with a rotating shaft, an upper end of which can be embedded inside the upper compartment 120 and connected to the upper compartment 120. The impeller 140 and the upper compartment 120 are sequentially mounted on the rotating shaft, allowing the upper compartment 120 and the impeller 140 to rotate synchronously under the drive of the driving device 130.

The impeller 140, installed at the bottom shell 1212 of the upper compartment 120, is connected to the driving device 130 and located between the upper compartment 120 and the driving device 130. The impeller 140, driven by the driving device 130, rotates with the upper compartment 120, which causing the airflow that drawing external air in through the air inlet 124, passing through the air duct 123, and expelling the airflow through the air outlet 125.

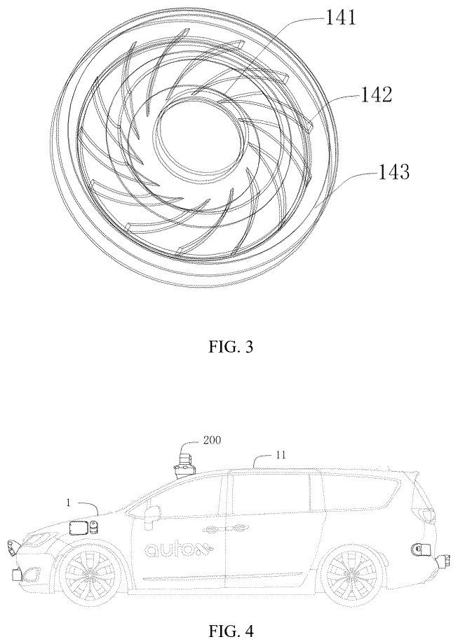

Referring to FIG. 3, a structure schematic diagram of an impeller is illustrated in FIG. 3.

The impeller 140 includes a hub 141, a plurality of blades 142, and a wheel disc 143. The hub 141 is located in a middle portion of the wheel disc 143 and protrudes towards the upper compartment 120. The plurality of blades 142 are arranged on a side of the wheel disc 143 away from the lower compartment 110. The impeller 140 is rotatably connected to the driving device 130 via the hub 141. During the rotation of the impeller 140, the plurality of blades 142 convert horizontal airflow to vertical airflow.

The heat sink 150 contacts with the inner shell 122, and is located within the air duct 123. The heat sink 150 includes a plurality of fins arranged on an outer surface of the inner shell 122. The position of the heat sink 150 corresponds to the position of the optical machine 160. The heat sink 150 rotates with the upper compartment 120 driven the driving device 130. The plurality of fins absorb heat and dissipate it through convection. In this process, the surface area of the plurality of fins determines an cooling effect. The larger the surface area of the plurality of fins, the better the cooling effect; the smaller the surface area, the worse the cooling effect.

The optical machine 160 is disposed on the sidewall of the inner shell 122 of the upper compartment 120. The optical machine 160 and the heat sink 150 are disposed back-to-back in the upper compartment 120 with the sidewall of the inner shell 122 in between. The optical machine 160 rotates with the upper compartment 120 driven by the driving device 130. The optical machine 160 is provided with an transmitter and a receiver. The transmitter is configured to transmit a laser beam, the receiver is configured to receive an echo beam returned from the laser beam transmit. The optical machine 160 generates heat during operation.

The cooling structure 100 of the LiDAR mentioned-above enhances LiDAR cooling by providing the air duct in the upper compartment of the LiDAR and utilizing the driving device to drive the impeller to rotate with the upper compartment, so as to create airflow that drawing external air in through the air inlet and expel the airflow through the air outlet, which actively cooling the LiDAR. This approach achieves the same cooling effect with less cooling area, reducing the size and weight of the LiDAR and significantly improving the cooling effect of the LiDAR. Additionally, the impeller rotates with the self-rotation of the LiDAR, eliminating extra motors or moving parts, resulting in a compact and highly efficient structure. Furthermore, the impeller, blowing external air inward, creates a positive pressure inside the air duct, reducing dust ingress. This improves cooling efficiency.

To precisely sense complex driving environments, the LiDAR 200 needs enhanced ranging capability and resolution. Increasing laser power boosts ranging, while adding more lasers improves resolution. However, both raise the heat generation of optical machines arranged in the LiDAR 200.

In this embodiment, due to the complex and variable external environmental factors, to achieve precise perception of the complex and dynamic driving environment by the LiDAR 200, it is necessary to enhance the ranging capability and resolution of the LiDAR 200. Generally, increasing the ranging capability requires increasing the laser power, and improving resolution requires increasing the number of lasers, both of which would lead to increased heat generation in the optical machine 160. When the LiDAR 200 is in operation, the optical machine 160 is in operation, producing heat during its operation, which can compromise the performance, accuracy, and stability of the LiDAR if excessive.

Therefore, during the operation of the LiDAR 200, the driving device 130 is in operation, causing the rotating shaft of the driving device 130 to rotate, which drives the upper compartment 120 and the impeller 140 to rotate together, with the upper compartment 120 sleeved on the rotating shaft. The optical machine 160 and the heat sink 150 rotate synchronously with the upper compartment. The optical machine 160 generates heat, the heat of the upper compartment 120 of the cooling structure 100 of the LiDAR will be higher than that of external environment. Since the optical machine 160 and the heat sink are disposed back-to-back in the upper compartment 120, the heat generated by the optical machine 160 can be conducted to the heat sink 150. The impeller 140 accelerates the airflow by centrifugal force, drawing external cold air axially through the air inlet 124 and into the bottom shell 1212 of the upper compartment 120. As the cold air passes through the impeller 140 located in the bottom case 1212, it becomes radial airflow and then enters the air duct 123. The plurality of fins of the heat sink 150, after absorbing heat from the optical machine 160, undergo convective heat transfer with the cold air that has passed through the impeller 140 into the air duct 123, carrying away the heat. The heat is then exhausted through the air outlet 125 above the air duct 123 and dissipated into the external environment, reducing the temperature of the upper compartment 120 and thus completing an entire cooling process.

When the LiDAR 200 is not in operation, the driving device 130 stops working, the optical machine 160 is not in operation. The upper compartment 120 and the impeller 140 stop rotating.

In this embodiment, the LiDAR 200 provided is a mechanical rotating LiDAR. The LiDAR 200 can perform 360-degree horizontal field-of-view scanning of the surrounding environment, providing comprehensive surrounding environment information for autonomous driving systems. The LiDAR 200 comprises an optical machine 160 and the cooling structure 100 of the LiDAR mentioned-above. The cooling structure 100 of the LiDAR is configured to dissipate heat from the LiDAR 200. The specific structure of the cooling structure 100 of the LiDAR is described above and will not be repeated here.

The optical machine 160 is disposed on the sidewall of the inner shell 122 of the upper compartment 120. The optical machine 160 and the heat sink 150 are disposed back-to-back in the upper compartment 120 with the sidewall of the inner shell 122 in between. The optical machine 160 rotates with the upper compartment 120 driven by the driving device 130. The optical machine 160 is provided with an transmitter and a receiver. The transmitter is configured to transmit a laser beam, the receiver is configured to receive an echo beam returned from the laser beam transmit. The optical machine 160 generates heat during operation.

Referring to FIG. 4, a schematic diagram of a vehicle is illustrated in FIG. 4. A vehicle 1 provided includes a vehicle roof 11 and the LiDAR 200 mentioned-above. The LiDAR 200 can be installed on the vehicle roof 11.

In some feasible embodiments, the LiDAR 200 can also be installed on the body and the sides of the vehicle 1. Specifically, the LiDAR 200 can be installed on the front and rear bumpers, the vehicle roof 11, headlights, the hood, and other sides of the vehicle 1.

The cooling structure of the LiDAR 100, the LiDAR 200 and the vehicle 1 mentioned-above enhances LiDAR cooling by providing the air duct 123 in the upper compartment 120 of the LiDAR 200 and utilizing the driving device 130 to drive the impeller 140 to rotate with the upper compartment 120, so as to create airflow that drawing external air in through the air inlet 124 and expel the airflow through the air outlet 125. The cold air, through the rotation of the impeller 140, becomes a longitudinal airflow directed towards the air duct 123, where it undergoes convection with the hot airflow dissipated by the heat sink 150 through the air duct 123, dissipating the heat through the air outlet 125, thereby achieving active cooling of the LiDAR 200. This approach achieves the same cooling effect with less cooling area, reducing the size and weight of the LiDAR and significantly improving the cooling effect of the LiDAR 200. Additionally, the impeller 140 rotates with the self-rotation of the LiDAR 200, eliminating extra motors or moving parts, resulting in a compact and highly efficient structure. Furthermore, the impeller 140, blowing external air inward, creates a positive pressure inside the air duct 123, reducing dust ingress.

In the embodiments provided in the present invention, it should be understood that the disclosed systems, devices and methods can be implemented by other means. For example, the training method for a multi-task recognition network based on end-to-end described above is only schematic. For example, the division of the unit is only a logical function division. In actual implementation, there may be other division ways, for example, multiple units or components can be combined or integrated into another system, or some features can be ignored or not performed. On the other hand, the coupling or direct coupling or communication connection between each other shown or discussed may be indirect coupling or communication connection through some interface, device or unit, and may be electrical, mechanical or other.

It should be noted that the embodiments number of this invention above is for description only and do not represent the advantages or disadvantages of embodiments. And in this invention, the term “including”, “include” or any other variants is intended to cover a non-exclusive contain. So that the process, the devices, the items, or the methods includes a series of elements not only include those elements, but also include other elements not clearly listed, or also include the inherent elements of this process, devices, items, or methods. In the absence of further limitations, the elements limited by the sentence “including a . . . ” do not preclude the existence of other similar elements in the process, devices, items, or methods that include the elements.

The above disclosed preferred embodiments of the invention are intended only to assist in the elaboration of the invention. The preferred embodiment does not elaborate on all the details and does not limit the invention to a specific embodiment. Obviously, according to the contents of this instruction manual, a lot of amendments and changes can be made. These embodiments are selected and described in detail in this specification for the purpose of better explaining the principle and practical application of the invention, so that the technical personnel in the technical field can better understand and utilize the invention. The invention is limited only by the claims and their full scope and equivalents.

The above are only the preferred embodiments of this invention and do not therefore limit the patent scope of this invention. And equivalent structure or equivalent process transformation made by the specification and the drawings of this invention, either directly or indirectly applied in other related technical fields, shall be similarly included in the patent protection scope of this invention.

1. A cooling structure of a LiDAR, the cooling structure comprising:
an upper compartment, configured to mount an optical machine for emitting laser, the upper compartment defining with an air duct, and an air inlet and an air outlet that both communicated with the air duct;
a lower compartment, connected to the upper compartment, configured to support the upper compartment, the lower compartment supplying power to the upper compartment via wireless power supply, and transmitting signals through wireless communication; the air inlet located at a bottom portion of the upper compartment facing towards the lower compartment, the air outlet located at a top portion of the upper compartment away from the lower compartment;
a driving device, connected between the upper compartment and the lower compartment, configured to drive the upper compartment to rotate relative to the lower compartment; and
an impeller, connected to the driving device and located between the upper compartment and the driving device, the impeller, driven by the driving device, rotating with the upper compartment, which creating airflow that drawing external air in through the air inlet, and expelling the airflow through the air outlet.

2. The cooling structure according to claim 1, wherein the upper compartment comprises an inner shell and an outer shell, the inner shell is configured to seal the optical machine located therein; the outer shell covers an outer side of the inner shell and forms the air duct with a certain gap between the outer shell and the inner shell.

3. The cooling structure according to claim 2, wherein the outer shell comprises an upper shell and a bottom shell, the upper shell comprises the top portion, and a side wall that extend downward from the edge of the top portion toward the lower compartment; the bottom shell is fixed to a bottom portion of the side wall away from the top portion, the bottom shell is provided with an opening to form the air inlet, the impeller is installed at the bottom shell.

4. The cooling structure according to claim 2, wherein the cooling structure further comprises a heat sink, the heat sink contacts the inner shell, and is located within the air duct.

5. The cooling structure according to claim 2, wherein the heat sink comprises a plurality of fins arranged on an outer surface of the inner shell, the position of the heat sink corresponds to that of the optical machine.

6. The cooling structure according to claim 1, wherein the impeller comprises a hub, a plurality of blades, and a wheel disc, the hub is located in a middle position of the wheel disc and protrudes towards the upper compartment, the plurality of blades are arranged on a side of the wheel disc away from the lower compartment, the impeller is rotatably connected to the driving device via the hub.

7. The cooling structure according to claim 6, wherein the driving device is provided with a rotating shaft, the impeller and the upper compartment are sequentially mounted on the rotating shaft.

8. The cooling structure according to claim 7, wherein the air outlet is disposed at the edge of the top portion.

9. A LiDAR, the LiDAR comprising:
an optical machine; and
a cooling structure of the LiDAR, the cooling structure comprising:
an upper compartment, configured to mount an optical machine for emitting laser, the upper compartment defining with an air duct, and an air inlet and an air outlet that both communicated with the air duct;
a lower compartment, connected to the upper compartment, configured to support the upper compartment, the lower compartment supplying power to the upper compartment via wireless power supply, and transmitting signals through wireless communication; the air inlet located at a bottom portion of the upper compartment facing towards the lower compartment, the air outlet located at a top portion of the upper compartment away from the lower compartment;
a driving device, connected between the upper compartment and the lower compartment, configured to drive the upper compartment to rotate relative to the lower compartment; and
an impeller, connected to the driving device and located between the upper compartment and the driving device, the impeller, driven by the driving device, rotating with the upper compartment, which creating airflow that drawing external air in through the air inlet, and expelling the airflow through the air outlet.

10. The LiDAR according to claim 9, wherein the upper compartment comprises an inner shell and an outer shell, the inner shell is configured to seal the optical machine located therein; the outer shell covers an outer side of the inner shell and forms the air duct with a certain gap between the outer shell and the inner shell.

11. The LiDAR according to claim 10, wherein the outer shell comprises an upper shell and a bottom shell, the upper shell comprises the top portion, and a side wall that extend downward from the edge of the top portion toward the lower compartment; the bottom shell is fixed to a bottom portion of the side wall away from the top portion, the bottom shell is provided with an opening to form the air inlet, the impeller is installed at the bottom shell.

12. The LiDAR according to claim 10, wherein the cooling structure further comprises a heat sink, the heat sink contacts the inner shell, and is located within the air duct.

13. The LiDAR according to claim 10, wherein the heat sink comprises a plurality of fins arranged on an outer surface of the inner shell, the position of the heat sink corresponds to that of the optical machine.

14. The LiDAR according to claim 9, wherein the impeller comprises a hub, a plurality of blades, and a wheel disc, the hub is located in a middle position of the wheel disc and protrudes towards the upper compartment, the plurality of blades are arranged on a side of the wheel disc away from the lower compartment, the impeller is rotatably connected to the driving device via the hub.

15. The LiDAR according to claim 14, wherein the driving device is provided with a rotating shaft, the impeller and the upper compartment are sequentially mounted on the rotating shaft.

16. The LiDAR according to claim 15, wherein the air outlet is disposed at the edge of the top portion.

17. A vehicle, the vehicle comprising:
a vehicle roof; and
a LiDAR, disposed on the vehicle roof, the LiDAR comprising:
an optical machine; and
a cooling structure of the LiDAR, the cooling structure comprising:
an upper compartment, configured to mount an optical machine for emitting laser, the upper compartment defining with an air duct, and an air inlet and an air outlet that both communicated with the air duct;
a lower compartment, connected to the upper compartment, configured to support the upper compartment, the lower compartment supplying power to the upper compartment via wireless power supply, and transmitting signals through wireless communication; the air inlet located at a bottom portion of the upper compartment facing towards the lower compartment, the air outlet located at a top portion of the upper compartment away from the lower compartment;
a driving device, connected between the upper compartment and the lower compartment, configured to drive the upper compartment to rotate relative to the lower compartment; and
an impeller, connected to the driving device and located between the upper compartment and the driving device, the impeller, driven by the driving device, rotating with the upper compartment, which creating airflow that drawing external air in through the air inlet, and expelling the airflow through the air outlet.

18. The vehicle according to claim 17, wherein the upper compartment comprises an inner shell and an outer shell, the inner shell is configured to seal the optical machine located therein; the outer shell covers an outer side of the inner shell and forms the air duct with a certain gap between the outer shell and the inner shell.

19. The vehicle according to claim 17, wherein the impeller comprises a hub, a plurality of blades, and a wheel disc, the hub is located in a middle position of the wheel disc and protrudes towards the upper compartment, the plurality of blades are arranged on a side of the wheel disc away from the lower compartment, the impeller is rotatably connected to the driving device via the hub.

20. The vehicle according to claim 17, wherein the air outlet is disposed at the edge of the top portion.
